(19) United States
(12) Patent Application Publication
(10) Pub. No.: US 2019/0338092 A1
(43) Pub. Date: Nov. 7, 2019

(54) FLEXIBLE COLOR FILTER AND METHOD OF MANUFACTURING

(71) Applicant: Ares Materials Inc.

(72) Inventors: Radu REIT, Carrollton, TX (US); Adrian AVENDANO-BOLIVAR, Plano, TX (US); David ARREAGA-SALAS, Garland, TX (US)

(21) Appl. No.: 16/481,438

(22) PCT Filed: Jan. 24, 2018
(86) PCT No.: PCT/US18/15026

§ 371 Date: Jul. 26, 2019

Related U.S. Application Data
(60) Provisional application No. 62/453,858, filed on Feb. 2, 2017.

(51) Int. Cl. C08J 5/18; G02B 5/20; C08G 75/045; C08J 7/04; G03F 7/00; B29C 41/02

(52) U.S. Cl. CPC C08J 5/18; G02B 5/201; C08G 75/045; G02F 1/133516; G03F 7/0007; B29C 41/02; C08J 7/045

(57) ABSTRACT

Provided are flexible color filters and methods of manufacturing flexible color filters. An example flexible color filter comprises a transparent flexible substrate comprising a thermoset thiol-click polymer. An example method of manufacturing a flexible color filter comprises dispensing a release layer on a stiff carrier substrate; dispensing a polymer resin on the release layer; curing the polymer resin into a transparent film; fabricating a flexible color filter on the transparent film; and removing the flexible color filter from the release layer and stiff carrier substrate.

### BACKGROUND

Color filters are widely used components of display modules utilizing liquid crystals, electrophoretics, (organic) light emitting diodes, or any other technologies that serve to filter a source of white light into multiple bands of monochromatic light. Previously, the substrate onto which these color filters have been fabricated has been glass due to transparency, chemical resilience, and high-temperature dimensional stability of glass. However, the low flexibility of glass limits the use of glass as a substrate material for color filters in flexible displays.

### BRIEF SUMMARY

The presently disclosed subject matter provides novel and advantageous color filters, as well as methods for fabricating the same and methods for using the same. While conventional approaches to fabricate color filters rely on the transparency of glass in order to minimize the light absorption from the source and increase power efficiency and color fidelity, the use of a novel substrate material is proposed. The material has a transparency above 85% in the visible spectrum and haze below 2%. The use of the substrate material can lead to thinner, lighter and more resilient color filters for LCD displays. The substrate material may be used with color filter fabrication methods.

### BRIEF DESCRIPTION OF THE DRAWINGS

Illustrative embodiments of the present disclosure are described in detail below with reference to the attached drawing figures, which are incorporated by reference herein, and wherein:

FIG. 1 shows a cross-sectional view of a color filter according to an embodiment.

FIG. 2 shows a cross-sectional view of a color filter being released from a carrier according to an embodiment.

FIG. 3 shows a flow diagram of a method of fabricating a color filter according to an embodiment.

FIG. 4A is a top view of a black matrix after patterning according to an embodiment.

FIG. 4B is a cross-sectional view of the color filter stack of FIG. 1 including an indication of light flow through sub-pixels of the color filter stack according to an embodiment.

FIG. 5 is a cross-sectional view of a Fabry-Perot filter according to an embodiment.

The illustrated figures are only exemplary and are not intended to assert or imply any limitation with regard to the environment, architecture, design, or process in which different embodiments may be implemented.

### DETAILED DESCRIPTION

As used herein, “flexible” is defined as having the ability to bend to a bending radius of at least 5 mm for a minimum of 100,000 bending cycles. “Transparency” is defined herein as the ratio of the fluence of visible photons (e.g. those with a wavelength between 400 and 800 nm) through a material before and after introduction of the material in the optical path of a photon source and a photodetector. A material is “transparent” if it if the percentage of the ratio is 85% or greater. “Haze” is defined herein as the scattering of light as it passes through a transparent material specifically leading to decreased transparency. Haze values for the materials described may not be greater than 2%. “Thiol-click” is defined as the combination of one or more multifunctional thiol monomers and one or more multifunctional comonomers in a single mixture.

The presently described subject matter provides a fabrication method for a flexible color filter, which includes a polymeric resin that is deposited onto a stiff carrier substrate and cured into a polymer film. Atop this film, the color filter matrix is deposited including the black matrix pattern, the primary color cell patterns and the electrode array. After fabrication of the color matrix is complete, the completed color filter is removed from the stiff carrier substrate using any number of mechanical methods, including peeling, vacuum rolling, ultrasonic bathing or any combination thereof.

A material, such as, but not limited to, a Si wafer or a glass panel can be used as the stiff carrier substrate. A release layer comprising an alkali metal or alkaline earth metal silicate dehydrate may then be deposited atop the stiff carrier substrate via any sufficient fluid deposition method (e.g., slot-die coating, blade coating, spin-coating, etc.). A polymer resin is then cast on the carrier to work as a substrate for the color filter fabrication. The polymer resin may be made by mixing of multifunctional thiol monomers and co-monomers.

In the production of the polymer resin, the multifunctional thiol monomers and co-monomers may be mixed and the polymer resin may be injected into a reservoir (e.g., a pressurized reservoir). Uniform sheet production can be performed on the polymer resin, and the uniform sheet production may be performed by any sufficient method including, but not limited to, slot die coating, rod coating, blade coating, spin coating, reaction injection molding, or any combination thereof. The polymer resin may be cured using electromagnetic radiation such as heat, visible light, ultraviolet light, or any combination thereof. The polymer cured resin has a transparency of more than 90% in the visible range and haze below 1%. This is the desirable property for a color filter substrate since light transmission directly affects image quality and power consumption of an LCD display.

A black matrix pattern is used in order to prevent light leakage so the backlight only goes through the desired sub-pixels. This black matrix pattern may comprise, but is not limited to, chrome, a black colored photoresist, a light sensitive black ink, or any combination thereof. The black matrix pattern may be deposited using any sufficient deposition method including, but not limited to, spin-cast techniques, dye-cast techniques, printing techniques, thermal evaporation techniques, or any combination thereof. In some optional examples, a pre-bake at temperatures ranging from 60 to 100 degrees C. for 10 to 10,000 seconds may be used. Any sufficient photolithography method may be used for patterning the black matrix pattern using a system with a mask aligner, a stepper, a scanner, printing, or any combination thereof. The light exposure may be performed using a suitable light source such as g-line (436 nm), h-line (405 nm), i-line (365 nm), j-line (313 nm), or any combination thereof. The exposure time is defined by the material used as a photoresist. The material is baked from 10 to 10,000 seconds at 100 to 300 degrees C., depending on the used materials, to remove possible solvents. If chromium is used, then the metal may be wet etched or dry etched.

Once the black matrix pattern is fabricated, a colored resist is applied to the desired sub-pixels. The colored resist includes an organic layer that absorbs a desired wavelength of light to set the color of each sub-pixel. This colored resist may be deposited by any sufficient method including, but not limited to dye-coating, spin-coating, printing, evaporation, or any combination thereof. The colored resist material is soft-baked and patterned using photolithography as previously described. This will form a sub-pixel in the black matrix. The process is repeated 3 or 4 times to create all the colors needed in a pixel (e.g., red, green and blue for RGB, and red, green, blue, and yellow for RGBY). There might be other configuration of sub-pixels that can be formed using the same steps described above while varying the color of the resist used for filtering the light.

In another embodiment, after the black matrix, the color in sub-pixels may also be formed using a Fabry-Perot filter in which two reflective layers have a spacer layer interposed creating a cavity. In the Fabry-Perot filter, the color can be chosen by changing the thickness of the spacer layer to an integer multiple of one half of the wavelength of the resonant frequency. The reflective layers can be fabricated with, but not limited to, Ag or Ag alloys. And the spacer layer can be fabricated with, but not limited to, SiO2, Al2O3, TiO2, etc.

In all embodiments, once the sub-pixels have been defined, a conductive transparent layer is deposited by, but is not limited to, sputtering, evaporation, electro-spinning, spin-on coating, dye-coating, printing, or any combination thereof. The material for this layer may be, but is not limited to, Indium-Tin-Oxide (ITO), Indium-Zinc-Oxide (IZO), Aluminum-Zinc-Oxide (AZO), Ag nanowires or poly(3,4-ethylenedioxythiophene) polystyrene sulfonate (PEDOT:PSS). This layer will comprise the transparent electrode to connect the driving backplane layer with thin film transistors.

The conductive transparent layer might be patterned using, but not limited to, photolithography, laser ablation, or printing.

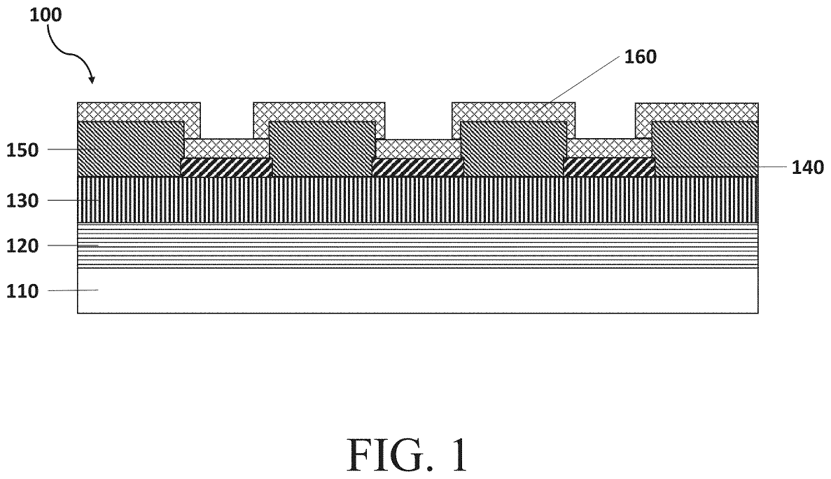

FIG. 1 shows a cross-section view of a color filter stack 100 fabricated on a carrier substrate 110. An interlayer release layer 120 has been disposed atop the carrier substrate 110, and the polymer substrate material 130 has been deposited and cured atop this interlayer release layer 120. Further, a black matrix pattern 140 was deposited and patterned. Color filter pixels fabricated from patterned colored resists 150 are also deposited and patterned atop the polymer substrate material 130, and a transparent conductive layer 160 is deposited to act as electrode for the TFT backplane.

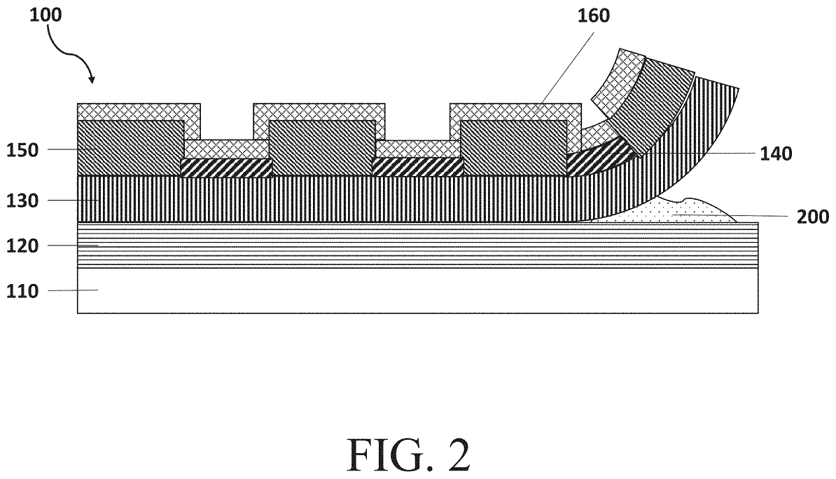

FIG. 2 shows a cross-section view of a color filter stack 100 fabricated on a carrier substrate 110 and release of the color filter stack 100 from the carrier substrate 110. The interlayer release layer 120 has been disposed atop the carrier substrate 110, and the polymer substrate material 130 has been deposited and cured atop the interlayer release layer 120. Additionally, the black matrix 140 and the color filter pixels 150 have been deposited and patterned atop the polymer substrate material 130. To begin the release of the color filter stack 100 from the carrier substrate 110, a fluid 200 is introduced at an interface between the polymer substrate material 130 and the interlayer release layer 120 to lower adhesion between the polymer substrate material 130 and the interlayer release layer 120. Lowering the adhesion between the polymer substrate material 130 and the interlayer release layer 120 enables delamination of the color filter stack 100 from the carrier substrate 110.

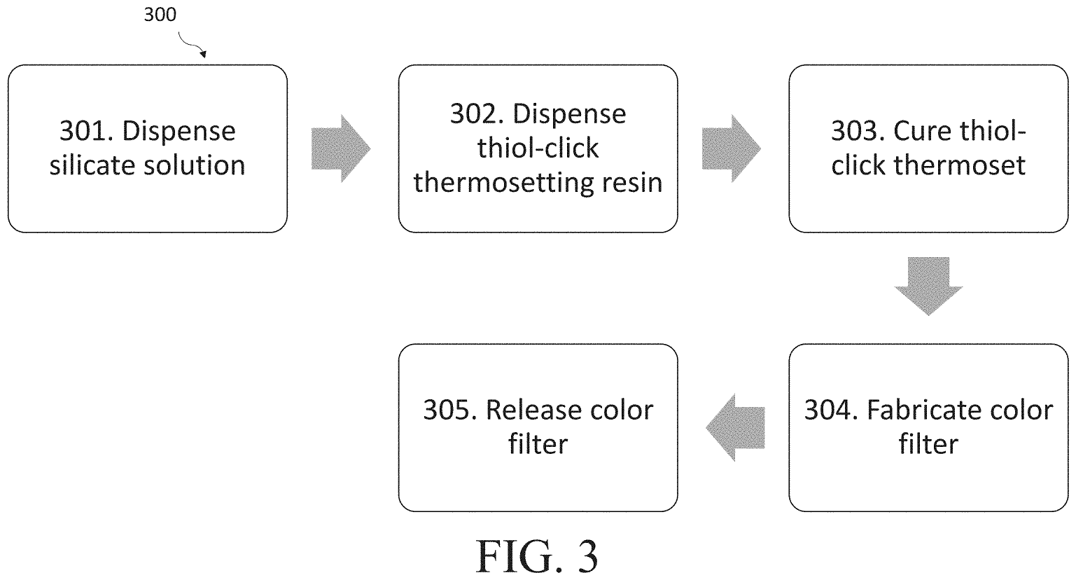

FIG. 3 is an example process flow diagram 300 for the fabrication of a flexible color filter stack, for example, flexible color filter stack 100 as described in FIG. 1 above. At block 301, a silicate solution is dispensed atop a carrier substrate and dried to form a release layer. Subsequently, at block 302, a thiol-click thermosetting resin is dispensed atop the dried silicate layer. The thiol-click thermosetting resin is then cured, at block 303, which enables fabrication of a color filter at block 304. At block 305, the flexible color filter is released from the carrier substrate.

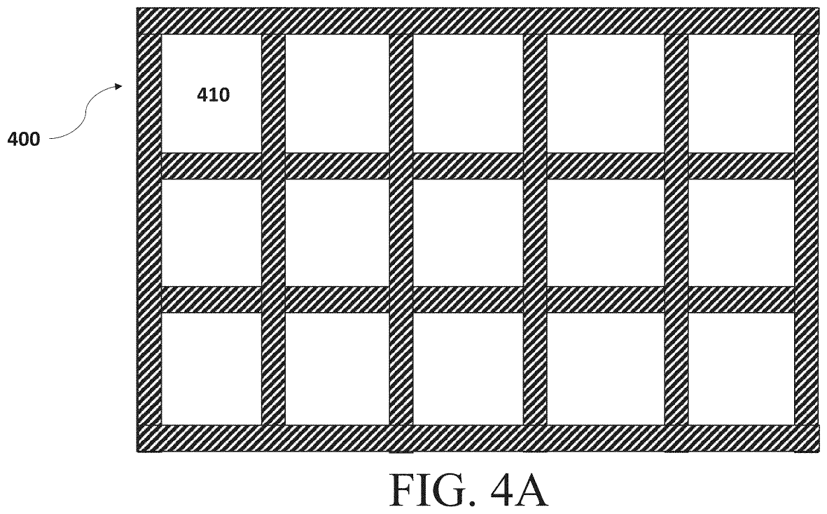

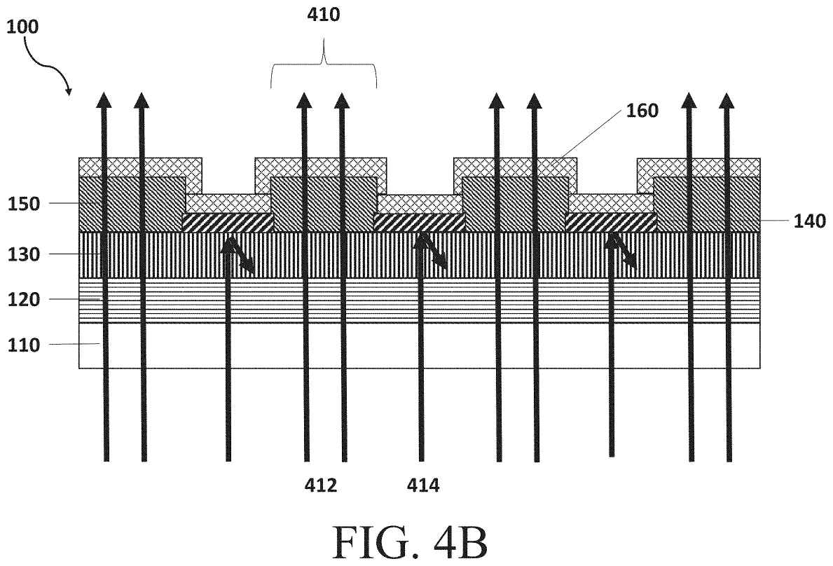

FIG. 4A is a top view 400 of a black matrix, for example black matrix 100 as described in FIG. 1 above, after patterning with a material with low transmission in order to prevent light leakage in between subpixels 410. As discussed above, the black matrix may be made from, but is not limited to, chrome, a black colored photoresist or a light sensitive black ink. The black matrix can be deposited using, but not limited to, spin-cast techniques, dye-cast techniques, printing techniques thermal evaporation techniques, or any combination thereof. A pre-bake at temperatures ranging from 60 to 100 degrees C. for 10 to 10,000 seconds may be performed. Photolithography can be used for patterning the black matrix using a system with a mask aligner, a stepper, a scanner, printing, or any combination thereof. The light exposure can be performed using any suitable light source such as g-line (436 nm), h-line (405 nm), i-line (365 nm), j-line (313 nm), or any combination thereof. The exposure time is defined by the material used as a photoresist. The material may be baked from 10 to 10,000 seconds at 100 to 300 degrees C., depending on the used materials, to remove possible solvents. If chromium is used, then the metal may be wet etched or dry etched.

FIG. 4B is a cross-sectional view of the color filter stack 100 including an indication of light flow 412 through the sub-pixels 410 of the color filter stack 102. The sub-pixels 410, each of which include color filter pixels 150, absorb a desired wavelength of light to set the color of the light flow 412 through each of the sub-pixels 410. Also depicted is light flow 414 that travels through the color filter stack 100 until the light flow 414 comes in contact with the black matrix 103/203. The black matrix 103 prevents the light flow 414 from passing through the entire color filter stack 100, and prevents light leakage between the sub-pixels 410.

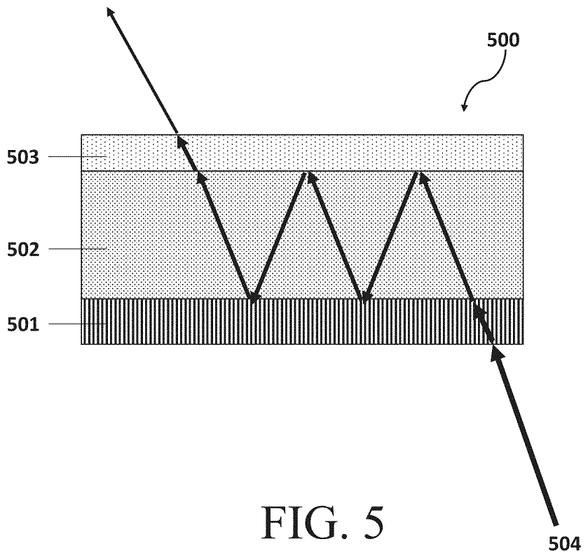

FIG. 5 is a cross-sectional view of a Fabry Perot filter 500 where light 505 goes through a backside of a thin reflective layer 501 into a medium 502 with a refractive index between 1.3 and 2.6. The light 504 is reflected between 501 and another reflective material 503 before finally exiting through 503. Interference between the reflected beams of light 504 may allow only certain wavelengths to exit the mirrors, thus “filtering” the input light and setting a color of the light 504 that exits the filter 500. As discussed above, the Fabry Perot filter 500 may be installed in the sub-pixels 410 in place of the color filter pixels 130.

In some embodiments, the flexible color filters may comprise a thermoset thiol-click polymer. The thermoset thiol-click polymer may be prepared by curing a monomer mixture. The monomer mixture may comprise from about 25 wt % to about 65 wt % of one or more multifunctional thiol monomers and from about 25 wt % to about 65 wt % of one or more multifunctional co-monomers. The flexible color filters may further comprise an interfacial adhesion layer and a rigid electronic component. The monomer mixture may further comprise from about 0.001 wt % to about 10 wt % of small molecule additive. The small molecule additive may comprise an acetophenone; a benzyl compound; a benzoin compound; a benzophenone; a quinone; a thioxanthone; azobisisobutyronitrile; benzoyl peroxide; hydrogen peroxide, or a combination thereof. The multifunctional thiol monomers may comprise trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy) ethyl] isocyanurate; 3,4-ethylenedioxythiophene; 1,10-decanedithiol; tricyclo[5.2.1.02,6]decanedithiol; Benzene-1,2-dithiol; and trithiocyanuric acid; dipentaerythritol hexakis(3-mercaptopropionate); 2,3-Di((2-mercaptoethyl)thio)-1-propanethiol; Dimercaptodiethyl sulfide; Ethoxylated Trimethylpropan-tri(3-mercapto-propionate); Ethoxylated Trimethylpropantri(3-mercapto-propionate); Polycaprolactone tetra 3-mercaptopropionate; Di-Pentaerythritolhexakis (3-mercaptopropionate); Di-Trimethylolpropanetetra (3-mercaptopropionate); Glycoldi (3-mercaptopropionate); Pentaerythritoltetramercaptoacetate; Trimethylol-propanetri-mercaptoacetate; Glycoldi-mercaptoacetate; or a combination thereof. The multifunctional co-monomers may comprise 1,3,5-triallyl-1,3,5-triazine-2,4,6 (1H,3H,5H)-trione; tricyclo[5.2.1.02,6] decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene) bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; ethylidene norbornene; or a combination thereof.

The flexible color filters may comprise a thermoset polymer. The flexible color filters may be capable of being processed at a temperature higher than the glass transition temperature of the thermoset polymer.

In some embodiments, methods of fabricating a flexible color filters are provided. An example method comprises preparing a monomer mixture and curing the monomer mixture to form a flexible polymeric substrate film comprising a thermoset thiol-click polymer as a substrate for thin-film processing. The pre-thermoset monomer mixture may comprise from about 25 wt % to about 65 wt % of one or more multifunctional thiol monomers and from about 25 wt % to about 65 wt % of one or more multifunctional co-monomers.

The pre-thermoset monomer mixture may further comprise from about 0.001 wt % to about 10 wt % of small molecule additives. The small molecule additive may comprise at least one of the following: an acetophenone; a benzyl compound; a benzoin compound; a benzophenone; a quinone; a thioxanthone; azobisisobutyronitrile; benzoyl peroxide; and hydrogen peroxide. The multifunctional thiol monomers may comprise at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl] isocyanurate; 3,4-ethylenedioxythiophene; 1,10-decanedithiol; tricyclo[S.2.1.02,6]decanedithiol; Benzene-1,2-dithiol; and trithiocyanuric acid, dipentaerythritol hexakis(3-mercaptopropionate); 2,3-Di((2-mercaptoethyl)thio)-1-propanethiol; Dimercaptodiethyl sulfide; Ethoxylated Trimethylpropan-tri(3-mercapto-propionate); Ethoxylated Trimethylpropantri(3-mercapto-propionate); Polycaprolactone tetra 3-mercaptopropionate; Di-Pentaerythritolhexakis (3-mercaptopropionate); Di-Trimethylolpropanetetra (3-mercaptopropionate); Glycoldi (3-mercaptopropionate); Pentaerythritoltetramercaptoacetate; Trimethylol-propanetri-mercaptoacetate; Glycoldi mercaptoacetate; or a combination thereof. The multifunctional co-monomers may comprise at least one of the following: 1,3,5-triallyl-1,3,5-triazine-2,4,6 (1H,3H,SH)-trione; tricyclo[S.2.1.02,6] decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene) bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; ethylidene norbornene; or a combination thereof.

In one embodiment, the release layer is a silicate solution comprising alkali metal silicates including, but not limited to, lithium silicate, sodium silicate, potassium silicate, rubidium silicate, cesium silicate, francium silicate, or any combinations thereof. In another embodiment, the release layer comprises alkaline earth metal silicates including, but not limited to, beryllium silicate, magnesium silicate, calcium silicate, strontium silicate, barium silicate, radium silicate, or any combinations thereof. In a further embodiment, the release layer comprises a combination of alkali metal silicates and alkaline earth metal silicates. In examples, the silicate(s) is solubilized in water to form a 0.01 to 50% w/w silicate solution, which may be dispensed atop a carrier via a coating method (e.g., spin-coating). The produced film may then be desolvated by increasing temperature (e.g., exposure to 125° C. for 10 minutes) or other method to form the silicate bonding layer. After the silicate bonding layer is formed, the flexible substrate may be formed atop the silicate bonding layer. In one embodiment, the flexible substrate is formed by solution coating and curing a flexible substrate material atop the silicate bonding layer. After microfabrication, the silicate bonding layer between the flexible substrate and the carrier may be exposed via mechanical excision, and water or other solvent may be introduced at the interface to resolvate the silicate. The flexible substrate may then be removed from the carrier via a tensile force less than 1 kgf/m as measured at or below a 90° angle between the carrier and the released flexible substrate. An applied release force resulting from the tensile force and the angle between the carrier and the flexible substrate may be calculated using the following equation:

### Example 1

A 370 mm by 470 mm glass panel is used as a carrier. A thin release layer is deposited by dye-coating and baked to remove solvents. A 50 um layer of polymer resin is slot-die coated on top of the thin release layer and cured for an hour at 250 degrees C. while irradiated with UV light. After curing the polymer resin, a 1.4 um layer of a light sensitive black ink is coated on the polymer resin by spin coating. The sample is then baked at 100 degrees C. for 2 minutes to remove solvents. Subsequently, a photomask is used to block UV light at a wavelength of 365 nm (i-line) and then developed to pattern a black matrix onto the polymer resin. The resulting sample is baked at 200 degrees C. for 2 minutes for hard-baking. After the hard-baking step, a layer of red colored resist is spun coated onto the sample with a thickness of 1.2 um. The resulting sample is then baked at 100 degrees C. for 2 minutes for curing. A photomask is used to pattern locations of the red sub-pixel on the black matrix patterned polymer resin. Afterwards, the resulting sample is developed and hard baked. A blue color resist and a green color resist can be used with the same process as the red color resist for the remaining two sub-pixels when using an RGB configuration. After applying the color resists, 100 nm of ITO is sputtered to form a transparent electrode for thin film transistors of a driving backplane layer. The ITO is later patterned by laser ablation. The polymer substrate is then mechanically removed from the carrier.

### Example 2

The procedure of Example 1 in which an extra sub-pixel is used for yellow color in an RGBY configuration.

### Example 3

The procedure of Examples 1 or 2 for a thinner color filter in which the sub-pixels are fabricated using a single cavity Fabry-Perot filter with a spacer layer between two reflective layers using thin film materials such as, but not limited to SiO2, TiO2, Si or Ag.

What is claimed is:

1. A method of manufacturing a flexible color filter comprising:
dispensing a release layer on a stiff carrier substrate;
dispensing a polymer resin on the release layer;
curing the polymer resin into a transparent film;
fabricating a flexible color filter on the transparent film; and
removing the flexible color filter from the release layer and stiff carrier substrate.

2. The method of claim 1, wherein the release layer is a silicate bonding layer dispensed from a silicate solution.

3. The method of claim 1, wherein removing the flexible color filter comprises utilizing a vacuum roller, a blade wedge, a tensile grip, an ultrasonic bath, or any combination thereof to remove the flexible color filter from the stiff carrier substrate.

4. The method of claim 1, wherein fabricating the flexible color filter on the transparent film comprises:
manufacturing a black matrix comprising a layer of chrome, black photoresist, or black sensitive ink, wherein the black matrix is baked and processed using photolithography to generate a black matrix pattern;
manufacturing at least one layer of a color resist, wherein the at least one layer of color resist is baked and processed using photolithography to pattern the at least one layer of color resist; and
depositing a conductive transparent material on the flexible color filter, wherein the conductive transparent material layer is a patterned layer.

5. The method of claim 4, wherein the conductive transparent material comprises Indium-Tin-Oxide, PEDOT:PSS, silver nanowires, or any combination thereof.

6. The method of claim 4, wherein the conductive transparent material is patterned using laser ablation, photolithography, shadowmasks, or any combination thereof.

7. The method of claim 1, wherein the fabrication of the sub-pixels is done using a Fabry-Perot filter comprising:
a spacer layer positioned between two reflective layers to create a cavity, wherein the spacer layer comprises a material with a refractive index between 1.3 and 2.6, and the spacer layer comprises a variable thickness ranging from 10 to 500 nm to control a sub-pixel color.

8. The method of claim 7, wherein the reflective layers comprise silver or silver alloys.

9. A flexible color filter, comprising:
a transparent flexible substrate comprising a thermoset thiol-click polymer.

10. The flexible color filter according to claim 9, wherein the thermoset thiol-click polymer is prepared by curing a monomer mixture, and wherein the monomer mixture comprises from approximately 25 wt % to about 65 wt % of one or more multifunctional thiol monomers and from approximately 25 wt % to about 65 wt % of one or more multifunctional co-monomers.

11. The flexible color filter according to claim 10, wherein the monomer mixture further comprises from about 0.001 wt % to about 10 wt % of small molecule additive.

12. The flexible color filter according to claim 11, wherein the small molecule additive comprises an acetophenone, a benzyl compound, a benzoin compound, a benzophenone, a quinone, a thioxanthone, azobisisobutyronitrile, benzoyl peroxide, hydrogen peroxide, or a combination thereof.

13. The flexible color filter according to claim 10, wherein the multifunctional thiol monomers
comprise trimethylolpropane tris(3-mercaptopropionate), trimethylolpropane tris(2-mercaptoacetate), pentaerythritol tetrakis(2-mercaptoacetate), pentaerythritol tetrakis(3-mercaptopropionate), 2,2′-(ethylenedioxy)diethanethiol, 1,3-Propanedithiol, 1,2-ethanedithiol, 1,4-butanedithiol, tris[2-(3-mercaptopropionyloxy)ethyl] isocyanurate, 3,4-ethylenedioxythiophene, 1,10-decanedithiol, tricyclo[5.2.1.02,6]decanedithiol, Benzene-1,2-dithiol, trithiocyanuric acid, or a combination thereof, and
wherein the multifunctional co-monomers comprise 1,3,5-triallyl-1,3,5-triazine-2,4,6 (1H,3H,SH)-trione, tricyclo[S.2.1.02,6] decanedimethanol diacrylate; divinyl benzene, diallyl bisphenol A (diacetate ether), diallyl terephthalate, diallyl phthalate, diallyl maleate, trimethylolpropane diallyl ether, ethylene glycol dicyclopentenyl ether acrylate, diallyl carbonate, diallyl urea, 1,6-hexanediol diacrylate, cinnamyl cinnamate, vinyl cinnamate, allyl cinnamate, allyl acrylate, crotyl acrylate, cinnamyl methacrylate, trivinylcyclohexane, 1,4-cyclohexanedimethanol divinyl ether, poly(ethylene glycol) diacrylate, tricyclodecane dimethanol diacrylate, bisphenol A ethoxylate diarylate, tris[2-(acryloyloxy ethyl)] isocyanurate, trimethylolpropane triacrylate, pentaethrytolpropane tetraacrylate, dipentaethrytolpropane penta-/hexa-acrylate, poly(ethylene glycol) dimethacrylate, dimethanol dimethacrylate, bisphenol A ethoxylate dimetharylate, trimethylolpropane trimethacrylate, pentaethrytolpropane tetramethacrylate, bisphenol A diglycidyl Ether, neopentyl glycol diglycidyl ether, tris(2,3-epoxypropyl) isocyanurate, trimethylolpropane triglycidyl ether i. 1,1′-(methylenedi-4,1-phenylene) bismaleimide, 1,6-di(maleimido)hexane, 1,4-di(maleimido)butane, N,N′-(1,3-phenylene)dimaleimide, isophorone diisocyanate, xylylene diisocyanate, tolylene diisocyanate, 1,4-diisocyanatobutane, 1,6-diisocyanatohexane, 1,8-diisocyanatooctane, vinyl norbornene, dicyclopentadiene, ethylidene norbornene, or a combination thereof.

14. The flexible color filter according to claim 10, wherein the multifunctional thiol monomers comprise at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl]isocyanurate; 3,4-ethylenedioxythiophene; 1,10-decanedithiol; tricyclo[S.2.1.02,6]decanedithiol; Benzene-1,2-dithiol; and trithiocyanuric acid.

15. The flexible color filter according to claim 10, wherein the multifunctional co-monomers comprise at least one of the following: 1,3,5-triallyl-1,3,5-triazine-2,4,6 (1H,3H,SH)-trione; tricyclo[S.2.1.02,6] decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene) bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.
